(19) United States
(12) Patent Application Publication
(10) Pub. No.: US 2025/0380471 A1
(43) Pub. Date: Dec. 11, 2025

(54) SILICON CARBIDE SEMICONDUCTOR DEVICE

(71) Applicant: FUJI ELECTRIC CO., LTD., Kawasaki-shi (JP)

(72) Inventor: Akimasa KINOSHITA, Matsumoto-city (JP)

(73) Assignee: FUJI ELECTRIC CO., LTD., Kawasaki-shi (JP)

(21) Appl. No.: 19/313,075

(22) Filed: Aug. 28, 2025

Related U.S. Application Data
(63) Continuation of application No. PCT/JP2024/024513, filed on Jul. 5, 2024.

(30) Foreign Application Priority Data
Sep. 14, 2023 (JP) 2023-149645

(51) Int. Cl. H10D 62/10; H10D 30/01; H10D 30/66; H10D 62/00; H10D 62/832

(52) U.S. Cl. CPC H10D 62/109; H10D 30/0297; H10D 30/668; H10D 62/054; H10D 62/8325

(57) ABSTRACT

A semiconductor device, including: a silicon carbide semiconductor substrate; a first semiconductor layer provided on the semiconductor substrate; a second semiconductor layer provided on the first semiconductor layer; first and second semiconductor regions selectively provided in the second semiconductor layer; a plurality of trenches penetrating through the first semiconductor regions and the second semiconductor layer; a plurality of gate electrodes respectively provided in the trenches via gate insulating films; a plurality of high-concentration regions provided in the first semiconductor layer, respectively facing the trenches in a depth direction; a plurality of connecting regions provided in the first semiconductor layer, contacting the high-concentration regions and the second semiconductor layer; a plurality of first electrodes provided on the first and second semiconductor regions; and a second electrode provided on the semiconductor substrate. Both the second semiconductor regions and the connecting regions are periodically disposed in a longitudinal direction of the trenches.

### CROSS REFERENCE TO RELATED APPLICATIONS

This is a continuation application of International Application PCT/JP2024/024513 filed on Jul. 5, 2024 which claims priority from a Japanese Patent Application No. 2023-149645 filed on Sep. 14, 2023, the contents of which are incorporated herein by reference.

### BACKGROUND OF THE INVENTION

### 1. Field of the Invention

The present disclosure relates to a silicon carbide semiconductor device.

### 2. Description of the Related Art

A conventionally known semiconductor device includes a carrier transport layer of a first conductivity type; an implantation control region of a second conductivity type, provided at an upper surface of the carrier transport layer; an upper embedded region of the second conductivity type in contact with a lower surface of the implantation control region; and lower embedded regions of the second conductivity type, in contact with bottom surfaces of trenches and a lower surface of an upper embedded region; and between the trenches, the lower embedded regions are apart from each other via the carrier transport layer (for example, refer to International Publication No. WO 2022/137789).

### SUMMARY OF THE INVENTION

According to an embodiment of the present disclosure, a silicon carbide semiconductor device includes: a silicon carbide semiconductor substrate of a first conductivity type, the silicon carbide semiconductor substrate having a first main surface and a second main surface opposite to each other; a first semiconductor layer of the first conductivity type, provided at the first main surface of the silicon carbide semiconductor substrate, the first semiconductor layer having a dopant concentration lower than a dopant concentration of the silicon carbide semiconductor substrate, the first semiconductor layer having a first surface and a second surface opposite to each other, the second surface facing the silicon carbide semiconductor substrate; a second semiconductor layer of a second conductivity type, provided at the first surface of the first semiconductor layer, the second semiconductor layer having a first surface and a second surface opposite to each other, the second surface facing the first semiconductor layer; a plurality of first semiconductor regions of the first conductivity type, selectively provided in the second semiconductor layer at the first surface thereof; a plurality of second semiconductor regions of the second conductivity type, selectively provided in the second semiconductor layer at the first surface thereof, the plurality of second semiconductor regions being in contact with the plurality of first semiconductor regions and the second semiconductor layer; a plurality of trenches penetrating through the plurality of first semiconductor regions and the second semiconductor layer and reaching the first semiconductor layer; a plurality of gate insulating films respectively provided in the plurality of trenches; a plurality of gate electrodes respectively provided on the plurality of gate insulating films, in the plurality of trenches; a plurality of high-concentration regions of the second conductivity type, provided in the first semiconductor layer, respectively at positions facing the plurality of trenches in a depth direction; a plurality of connecting regions of the second conductivity type, selectively provided in the first semiconductor layer, closer to the second semiconductor layer than is the plurality of high-concentration regions and closer to the silicon carbide semiconductor substrate than is the second semiconductor layer, the plurality of connecting regions being in contact with the plurality of high-concentration regions and the second semiconductor layer; a plurality of first electrodes provided at surfaces of the plurality of first semiconductor regions and surfaces of the plurality of second semiconductor regions; and a second electrode provided at the second main surface of the silicon carbide semiconductor substrate. The plurality of second semiconductor regions is periodically disposed in a longitudinal direction of the plurality of trenches. The plurality of connecting regions is disposed periodically in the longitudinal direction of the plurality of trenches, in regions not overlapping with the plurality of second semiconductor regions in a plan view of the silicon carbide semiconductor device.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a perspective view depicting a structure of a silicon carbide semiconductor device according to a first embodiment.

FIG. 2A is a cross-sectional view depicting the structure of the silicon carbide semiconductor device according to the first embodiment, along cutting line A-A′ in FIG. 1.

FIG. 2B is a cross-sectional view depicting the structure of the silicon carbide semiconductor device according to the first embodiment, along cutting line B-B′ in FIG. 1.

FIG. 2C is a cross-sectional view depicting the structure of the silicon carbide semiconductor device according to the first embodiment, along cutting line C-C′ in FIG. 1.

FIG. 3A is a plan view depicting the structure of the silicon carbide semiconductor device according to the first embodiment, at a depth D indicated in FIGS. 2A to 2C.

FIG. 3B is a plan view depicting the structure of the silicon carbide semiconductor device according to the first embodiment, at a depth E indicated in FIGS. 2A to 2C.

FIG. 3C is a plan view depicting the structure of the silicon carbide semiconductor device according to the first embodiment, at a depth F indicated in FIGS. 2A to 2C.

FIG. 4 is a perspective view depicting a portion of a silicon carbide semiconductor device of a comparison example.

FIG. 5 is a perspective view depicting a portion of the silicon carbide semiconductor device of the comparison example.

FIG. 6 is a perspective view depicting a portion of the silicon carbide semiconductor device according to the first embodiment.

FIG. 7 is a perspective view depicting a portion of the silicon carbide semiconductor device according to the first embodiment.

FIG. 8 is a perspective view depicting current density of the silicon carbide semiconductor device of the comparison example.

FIG. 9 is a perspective view depicting current density of the silicon carbide semiconductor device according to the first embodiment.

FIG. 10 is a perspective view depicting a depletion region of the silicon carbide semiconductor device of the comparison example.

FIG. 11 is a perspective view depicting the depletion region of the silicon carbide semiconductor device of the comparison example.

FIG. 12 is a perspective view depicting a depletion region of the silicon carbide semiconductor device according to the first embodiment.

FIG. 13 is a perspective view depicting the depletion region of the silicon carbide semiconductor device according to the first embodiment.

FIG. 14 is a graph depicting feedback capacitance with respect to drain voltage in the silicon carbide semiconductor device according to the first embodiment and the silicon carbide semiconductor device of the comparison example.

FIG. 15 is a perspective view depicting the structure of the silicon carbide semiconductor device according to a second embodiment.

FIG. 16 is a cross-sectional view depicting the structure of the silicon carbide semiconductor device according to the second embodiment, along cutting line C-C′ in FIG. 15.

FIG. 17 is a plan view depicting the structure of the silicon carbide semiconductor device according to the second embodiment, at a depth D in FIG. 16.

FIG. 18 is a perspective view depicting the structure of the silicon carbide semiconductor device according to a third embodiment.

FIG. 19 is a cross-sectional view of the structure of the silicon carbide semiconductor device according to the third embodiment, along cutting line A-A′ in FIG. 18.

FIG. 20 is a plan view of the structure of the silicon carbide semiconductor device according to the third embodiment, at the depth E in FIG. 18.

FIG. 21A is a cross-sectional view depicting the structure of the silicon carbide semiconductor device according to a fourth embodiment, along cutting line A-A′ in FIG. 22A.

FIG. 21B is a cross-sectional view depicting the structure of the silicon carbide semiconductor device according to the fourth embodiment, along cutting line C-C′ in FIG. 22A.

FIG. 22A is a plan view of the structure of the silicon carbide semiconductor device according to the fourth embodiment depicted in FIG. 21A, at the depth D in FIG. 21B.

FIG. 22B is a plan view of the structure of the silicon carbide semiconductor device according to the fourth embodiment depicted in FIG. 21A, at the depth E in FIG. 21B.

FIG. 23A is a cross-sectional view of the structure of the silicon carbide semiconductor device according to a fifth embodiment, along cutting line A-A′ in FIG. 24A.

FIG. 23B is a cross-sectional view of the structure of the silicon carbide semiconductor device according to the fifth embodiment, along cutting line C-C′ in FIG. 24A.

FIG. 24A is a plan view of the structure of the silicon carbide semiconductor device according to the fifth embodiment depicted in FIG. 23A, at the depth D in FIG. 23B.

FIG. 24B is a plan view of the structure of the silicon carbide semiconductor device according to the fifth embodiment depicted in FIG. 23A, at the depth E in FIG. 23B.

FIG. 25 is a cross-sectional view depicting the structure of the silicon carbide semiconductor device of the comparison example, along cutting line A-A′ in FIG. 27.

FIG. 26 is a cross-sectional view depicting the structure of the silicon carbide semiconductor device of the comparison example, along cutting line B-B′in FIG. 27.

FIG. 27 is a perspective view depicting the structure of the silicon carbide semiconductor device of the comparison example.

### DETAILED DESCRIPTION OF THE INVENTION

First, problems associated with the conventional techniques are discussed. In the structure of the conventional semiconductor device, there are many structures per cell and thus, reducing the cell pitch is difficult. Therefore, reducing resistance is difficult in SiC, in which channel mobility is particularly low. Further, when the cell pitch is reduced for a complex structure, a problem arises in that p-type regions of pn junctions become narrower, whereby electric field concentration easily occurs and breakdown voltage decreases.

An outline of present disclosure is described. A silicon carbide semiconductor device according to the disclosure has the following characteristics. At a front surface of a silicon carbide semiconductor substrate of a first conductivity type, a first semiconductor layer of the first conductivity type is provided, the first semiconductor layer having a dopant concentration lower than a dopant concentration of the silicon carbide semiconductor substrate. A second semiconductor layer of a second conductivity type is provided at a first surface of the first semiconductor layer, opposite to a second surface thereof facing the silicon carbide semiconductor substrate. A plurality of first semiconductor regions of the first conductivity type is selectively provided in a surface layer of the second semiconductor layer, at a first surface of the second semiconductor layer, opposite to a second surface of the second semiconductor layer facing the silicon carbide semiconductor substrate. A plurality of second semiconductor regions of the second conductivity type is selectively provided in a surface layer of the second semiconductor layer, at a first surface of the second semiconductor layer, opposite to a second surface of the second semiconductor layer facing the silicon carbide semiconductor substrate, the plurality of second semiconductor regions being in contact with the plurality of first semiconductor regions and the second semiconductor layer. A plurality of trenches each penetrating through the plurality of first semiconductor regions and the second semiconductor layer and reaching the first semiconductor layer. A plurality of gate electrodes provided in the plurality of trenches, via a plurality of gate insulating films. A plurality of high-concentration regions of the second conductivity type is provided in the first semiconductor layer, at positions facing the plurality of trenches in a depth direction. A plurality of connecting regions of the second conductivity type is selectively provided in the first semiconductor layer, closer to the second semiconductor layer than is the plurality of high-concentration regions and closer to the silicon carbide semiconductor substrate than is the second semiconductor layer, the plurality of connecting regions being in contact with the plurality of high-concentration regions and the second semiconductor layer. A plurality of first electrodes is provided at surfaces of the plurality of first semiconductor regions and surfaces of the plurality of second semiconductor regions. A second electrode provided at a back surface of the silicon carbide semiconductor substrate. Each of the plurality of second semiconductor regions is periodically disposed in a longitudinal direction of the plurality of trenches; each of the plurality of connecting regions, in a plan view, is disposed periodically in the longitudinal direction of the plurality of trenches, in regions not overlapping with the plurality of second semiconductor regions.

According to the disclosure above, the p⁺-type connecting regions (plurality of connecting regions) are provided shallower than are the p⁺-type regions (high-concentration regions below the trenches) and deeper than is the p-type base region (second semiconductor layer). As a result, the area that the p⁺-type regions and the p⁺⁺-type contact regions are connected may be increased, fluctuation of the feedback capacitance may be suppressed, and switching (SW) loss may be reduced. Furthermore, the p⁺-type connecting regions reduce the area that the p-type base region is exposed toward the drain electrode, thereby making it difficult for high voltage to be applied to the p-type base region 13 and possible to increase the breakdown voltage.

Further, in the silicon carbide semiconductor device according to the present disclosure, in the disclosure above, a width of each of the plurality of connecting regions in a direction opposite to the longitudinal direction of the plurality of trenches is wider than a width of each of the plurality of second semiconductor regions in the direction opposite to the longitudinal direction of the plurality of trenches.

According to the disclosure above, the area that the plurality of connecting regions and the plurality of high-concentration regions below the trenches are connected to each other increases and the breakdown voltage may be improved.

Further, in the silicon carbide semiconductor device according to the present disclosure, in the disclosure above, each of the plurality of connecting regions, in the plan view, is provided between adjacent two of the plurality of trenches, in a dot-like shape, apart from the plurality of trenches.

According to the disclosure above, the channel region is wider and the resistance may be lower than in an instance in which each of the plurality of connecting regions is provided in a stripe-like shape.

Further, in the silicon carbide semiconductor device according to the present disclosure, in the disclosure above, each of the plurality of connecting regions, in the plan view, is provided between adjacent two of the plurality of trenches, in a stripe-like shape orthogonal to the longitudinal direction of the plurality of trenches, the plurality of connecting regions being in contact with the plurality of trenches.

According to the disclosure above, the area that the plurality of connecting regions and the plurality of high-concentration regions below the trenches are connected to each other increases and the breakdown voltage may be improved.

Further, in the silicon carbide semiconductor device according to the present disclosure, in the disclosure above, each of the plurality of second semiconductor regions, in the plan view, is provided between the adjacent two of the plurality of trenches, in a dot-like shape, apart from the plurality of trenches.

According to the disclosure above, each of the plurality of second semiconductor regions is provided in a dot-like shape, whereby the properties of the silicon carbide semiconductor device may be improved.

Further, in the silicon carbide semiconductor device according to the present disclosure, in the disclosure above, each of the plurality of second semiconductor regions, in the plan view, is provided between the adjacent two of the plurality of trenches, in a stripe-like shape orthogonal to the longitudinal direction of the plurality of trenches, the plurality of second semiconductor regions being in contact with the plurality of trenches.

According to the disclosure above, without an occurrence of misalignment of the plurality of second semiconductor regions, manufacturing costs may be lower compared to an instance in which the plurality of second semiconductor regions are provided in dot-like shapes.

Further, in the silicon carbide semiconductor device according to the present disclosure, in the disclosure above, a dopant concentration of the plurality of connecting regions is higher than a dopant concentration of the second semiconductor layer and lower than a dopant concentration of the plurality of high-concentration regions.

Further, in the silicon carbide semiconductor device according to the present disclosure, in the disclosure above, respective dopant concentrations of the second semiconductor layer, the plurality of connecting regions, and the plurality of high-concentration regions are 1×10¹⁷/cm³ or higher.

Findings underlying present disclosure are discussed. First, problems associated with a semiconductor device of a comparison example are discussed. Silicon carbide (SiC) is expected to replace silicon (Si) as a next-generation semiconductor material. Compared to a conventional semiconductor device element that uses silicon as a semiconductor material, a semiconductor device that uses silicon carbide as a semiconductor material (hereinafter, silicon carbide semiconductor device) has various advantages such as enabling resistance of a device in an on-state to be reduced to a few hundredths and application under higher temperature (200 degrees C. or higher) environments. These advantages are due to characteristics of the material itself in that a bandgap of silicon carbide is about 3 times larger than that of silicon and dielectric breakdown field strength thereof is nearly an order of magnitude greater than that of silicon.

Up to now, Schottky barrier diodes (SBDs) and vertical metal oxide semiconductor field effect transistors (MOSFETs) having a trench gate structure or a planar gate structure have become commercialized as silicon carbide semiconductor devices.

A planar gate structure is a metal oxide semiconductor (MOS) gate structure in which MOS gates are each provided in a plate-like shape on a front surface of a semiconductor substrate. A trench gate structure is a MOS gate structure in which MOS gates are embedded in trenches formed in a semiconductor substrate (semiconductor chip), at a front surface thereof, and in which a channel (inverse layer) is formed along sidewalls of the trenches in a direction orthogonal to the front surface of the semiconductor substrate. Thus, as compared to a planar gate structure in which a channel is formed along the front surface of the semiconductor substrate, unit cell (configuration unit of a device) density per unit area may be easily increased and current density per unit area may be easily increased, which is advantageous in terms of cost.

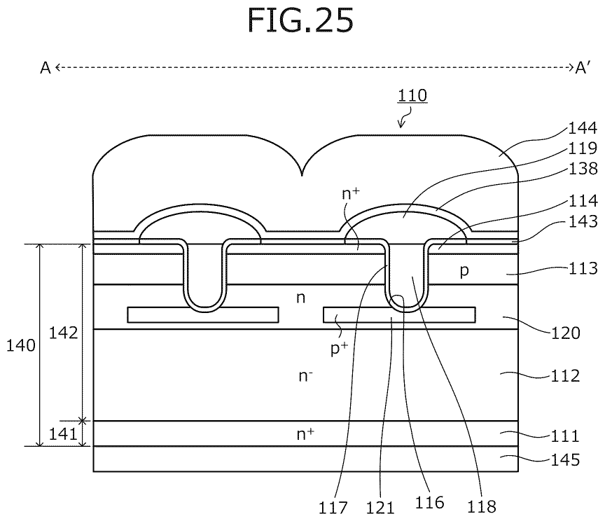

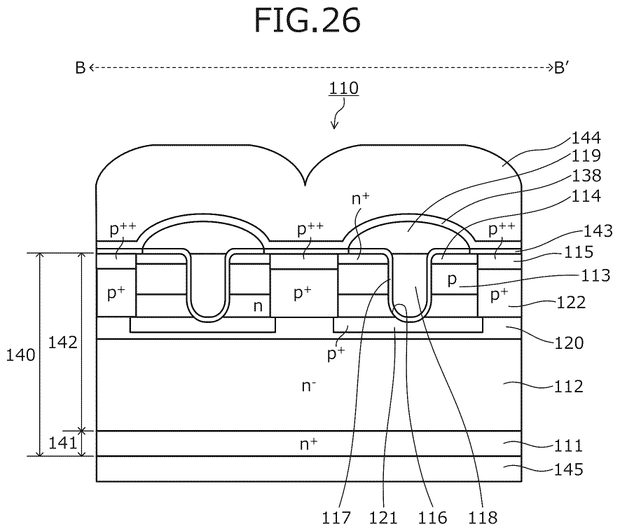

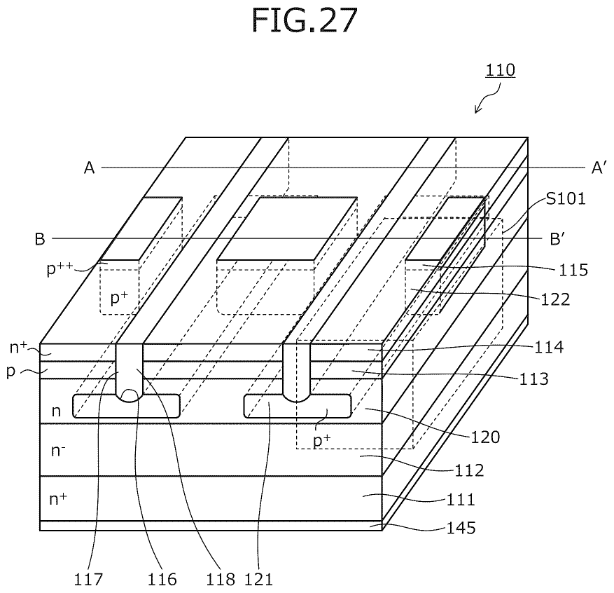

FIG. 25 is a cross-sectional view depicting a structure of a silicon carbide semiconductor device of the comparison example, along cutting line A-A′ in FIG. 27. FIG. 26 is a cross-sectional view depicting the structure of the silicon carbide semiconductor device of the comparison example, along cutting line B-B′ in FIG. 27. FIG. 27 is a perspective view depicting the structure of the silicon carbide semiconductor device of the comparison example. A semiconductor device 110 of the comparison example depicted in FIGS. 25 to 27 is a vertical MOSFET having a trench gate structure in a semiconductor substrate (semiconductor chip) 140 containing silicon carbide. In FIGS. 25 to 27, only an active region is depicted while an edge termination region is not depicted.

The semiconductor substrate 140 is formed by growing an n⁻-type silicon carbide layer 142 constituting an n⁻-type drift region 112 on a front surface of an n⁺-type starting substrate 141 containing silicon carbide. The semiconductor substrate 140 has, as a front surface, a main surface with the n⁻-type silicon carbide layer 142 and as a back surface, a main surface with the n⁺-type starting substrate 141. In an entire area of a back surface (back surface of the n⁺-type starting substrate 141) of the semiconductor substrate 140, a drain electrode 145 is provided. The n⁺-type starting substrate 141 constitutes an n⁺-type drain region 111.

At a surface of the n⁻-type drift region 112, opposite a surface thereof facing the n⁺-type silicon carbide substrate 111, an n⁻-type current spreading region 120 is provided. Further, in the n⁻-type current spreading region 120, p⁺-type regions 121 are selectively provided at positions facing bottoms of trenches 116 in a depth direction. The MOS gates of the trench gate structure are configured by a p-type base region 113, n⁺-type source regions 114, p⁺⁺-type contact regions 115, the trenches 116, gate insulating films 117, and gate electrodes 118. Further, p⁺-type regions 122 are selectively provided below the p⁺⁺-type contact regions 115.

Further, an interlayer insulating film 119 is provided on the gate electrodes 118 and in openings of the interlayer insulating film 119, ohmic electrodes 143 in contact with the n⁺-type source regions 114 and the p⁺⁺-type contact regions 115 are provided. A barrier metal 138 that prevents diffusion of metal atoms to the gate electrodes 118 is provided on the ohmic electrodes 143 and the interlayer insulating film 119. A source electrode 144 is provided on the barrier metal 138.

The p⁺-type regions 121, 122 are fixed to a potential of the source electrode 144 and deplete (or cause the n⁻-type current spreading region 120 to deplete, or both) when the MOSFET (silicon carbide semiconductor device 110) is off and have a function of relaxing electric field applied to the gate insulating films 117. The p⁺-type regions 121 are provided apart from the p-type base region 113 and face bottom surfaces of the trenches 116 in the depth direction. The p⁺-type regions 121 are partially connected to the p⁺-type regions 122 and are thereby electrically connected to the source electrode 144. FIG. 25 depicts a cross-section of a portion that is free of the p⁺-type regions 122 while FIG. 26 depicts cross-section of a portion where the p⁺-type regions 122 are provided and where the p⁺-type regions 122 and the p⁺-type regions 121 are connected. As described, the p⁺-type regions between the trenches 116 and

provided at a same depth as that of the p⁺-type regions 121 are eliminated, the JFET structure (structure of a portion through which current passes between the trenches 116) per cell is integrated into one. Furthermore, connection of the p⁺-type regions 121 and the p⁺⁺-type contact regions 115 is realized by the creation of the deep p⁺-type regions 122 in centers between the trenches 116.

As a result, the structure per unit cell is simplified, whereby the cell pitch may be shortened and reduced resistance of a SiC MOSFET having low channel mobility may be realized by the shortening of the cell pitch. Furthermore, the structure between the trenches 116 has more space, a width of the p⁺-type regions 121 below the trenches 116 may be increased, and a flat portion of the pn junctions becomes wider, whereby electric field concentration is relaxed and the breakdown voltage may be increased.

However, with this structure, the connection portions between the p⁺-type regions 121 below the trenches 116 and the p⁺-type regions 122 below the p⁺⁺-type contact regions 115 become narrow. Thus, a problem arises in that when high voltage is applied to the drain electrode 145 and a depletion layer spreads, neutral regions of the p⁺-type regions 122 and the p⁺-type regions 121 separate, the p⁺-type regions 121 become electrically floating, and feedback capacitance fluctuates rapidly, whereby increases in switching (SW) loss occur due to the fluctuation. Further, a problem arises in that high voltage is applied to the gate insulating films 117 due to the p⁺-type regions 121 that protect the trenches 116 being electrically floating. A further problem arises in that decreases in the breakdown voltage occur due to high voltage being applied to the channel as a result of the p-type base region 113, which constitutes a channel region, having a wide area on a side exposed to the drain electrode 145.

Embodiments of a silicon carbide semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

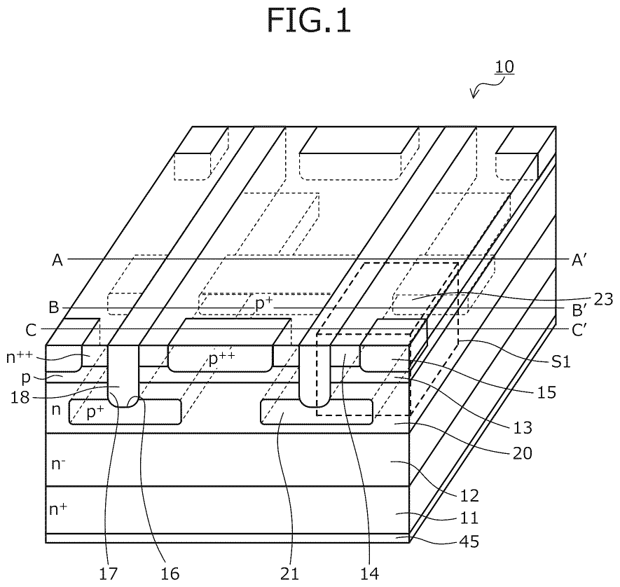

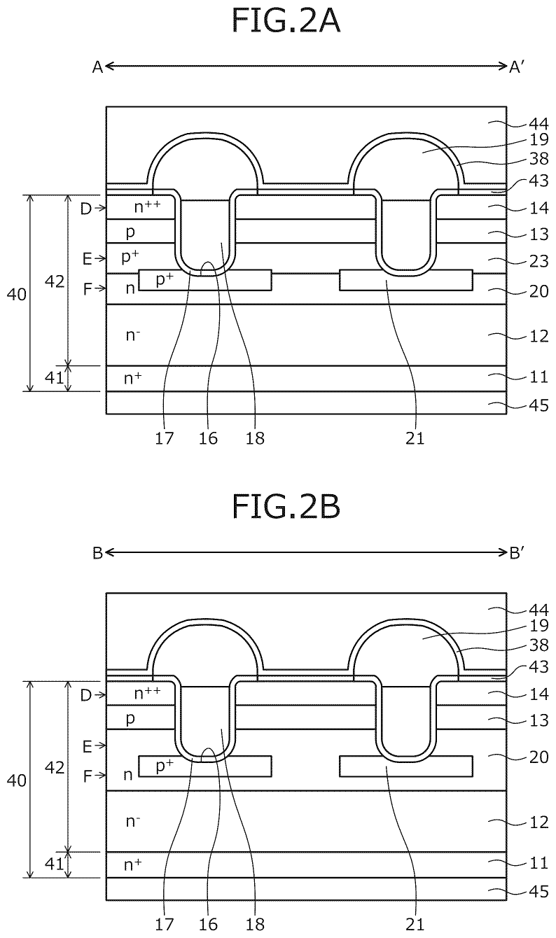

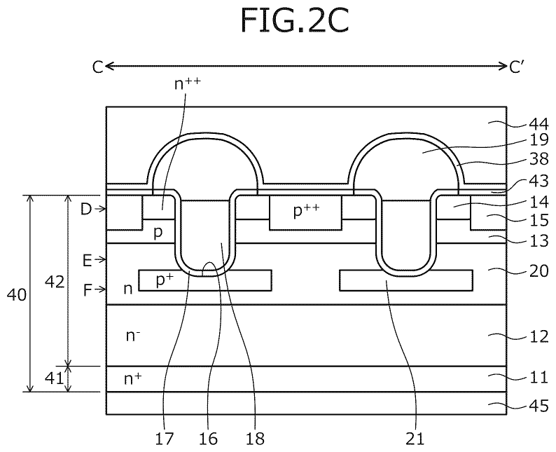

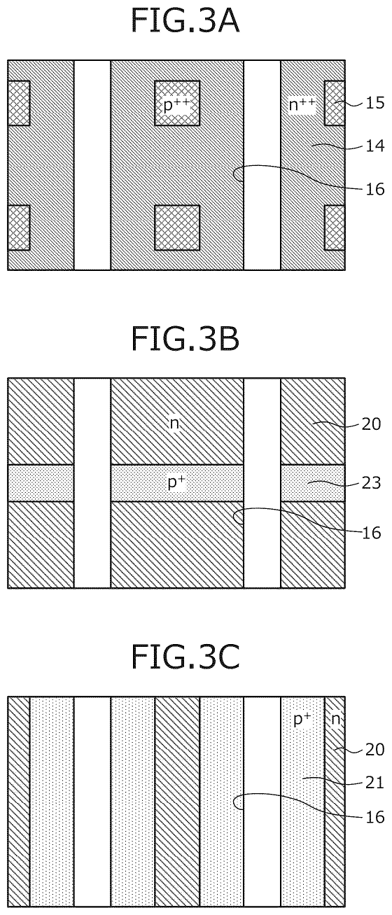

A structure of a silicon carbide semiconductor device according to a first embodiment is described. FIG. 1 is a perspective view depicting the structure of the silicon carbide semiconductor device according to the first embodiment. FIG. 2A is a cross-sectional view depicting the structure of the silicon carbide semiconductor device according to the first embodiment, along cutting line A-A′ in FIG. 1. FIG. 2B is a cross-sectional view depicting the structure of the silicon carbide semiconductor device according to the first embodiment, along cutting line B-B′ in FIG. 1. FIG. 2C is a cross-sectional view depicting the structure of the silicon carbide semiconductor device according to the first embodiment, along cutting line C-C′ in FIG. 1. FIG. 3A is a plan view depicting the structure of the silicon carbide semiconductor device according to the first embodiment, at a depth D indicated in FIGS. 2A to 2C. FIG. 3B is a plan view depicting the structure of the silicon carbide semiconductor device according to the first embodiment, at a depth E indicated in FIGS. 2A to 2C. FIG. 3C is a plan view depicting the structure of the silicon carbide semiconductor device according to the first embodiment, at a depth F indicated in FIGS. 2A to 2C. A silicon carbide semiconductor device 10 according to the first embodiment depicted in FIGS. 1 to 3C is a vertical MOSFET having a trench gate structure in a semiconductor substrate (semiconductor chip) 40 containing silicon carbide (SIC).

In FIGS. 1 to 3C, only an active region through which current flows during an on-state is depicted while an edge termination region that surrounds a periphery of the active region in a substantially rectangular shape and in which a voltage withstanding structure is provided is not depicted. The voltage withstanding structure has a function of relaxing electric field near a border between the active region and the edge termination region and sustaining a breakdown voltage. The breakdown voltage is a voltage limit at which no malfunction or destruction of the semiconductor device occurs.

In the semiconductor substrate 40, multiple unit cells (functional units of the device) of the MOSFET, each having a same structure (device structure), are disposed adjacent to each other so as to be in parallel. The semiconductor substrate 40 is formed by growing, by epitaxy, an n⁻-type silicon carbide layer 42 constituting an n⁻-type drift region (first semiconductor layer of a first conductivity type) 12 on a front surface of an n⁺-type starting substrate (silicon carbide semiconductor substrate (41) of the first conductivity type) 41 containing silicon carbide. The semiconductor substrate 40 has, as the front surface, a main surface (first main surface) having the n⁻-type silicon carbide layer 42 and, as a back surface, a main surface (second main surface) having an n⁺-type starting substrate 41.

The n⁺-type starting substrate 41 constitutes an n⁺-type drain region 11. To form each part of the active region, the semiconductor substrate 40 is grown by epitaxy in multiple stages on the n⁺-type starting substrate 41, starting with the n⁻-type silicon carbide layer 42 constituting the n⁻-type drift region 12. The n⁻-type drift region 12 is a portion of the n⁻-type silicon carbide layer 42 left at the dopant concentration at the time of epitaxial growth and free of diffused regions formed by ion implantation. The n⁻-type drift region 12 is in contact with the n⁺-type starting substrate 41 and is provided spanning the active region to a chip end. The n⁻-type silicon carbide layer 42 is formed by one stage of epitaxial growth, and a p-type base region 13, n⁺-type source regions 14, p⁺⁺-type contact regions 15, an n⁻-type current spreading region 20, p⁺-type regions 21, and p⁺-type connecting regions 23 may be formed by ion implantation.

In the active region of the first embodiment, the trench gate structure is provided. The trench gate structure is configured by the p-type base region (second semiconductor layer of a second conductivity type) 13, the n⁺-type source regions (first semiconductor regions of the first conductivity type) 14, the p⁺⁺-type contact regions (second semiconductor regions of the second conductivity type) 15, trenches 16, gate insulating films 17, and gate electrodes 18. The p-type base region 13, the n⁺-type source regions 14, and the p⁺⁺-type contact regions 15 are diffused regions formed by ion implantation in the n⁻-type silicon carbide layer 42. The p-type base region 13 is formed in an entire area between the front surface of the semiconductor substrate 40 and the n⁻-type drift region 12.

The n⁺-type source regions 14 and the p⁺⁺-type contact regions 15 are each selectively provided between the front surface of the semiconductor substrate 40 and the p-type base region 13, respective bottoms thereof (respective lower surfaces thereof: respective ends thereof facing the back surface of the semiconductor substrate 40) being in contact with the p-type base region 13. The n⁺-type source regions 14 are provided in contact with the p⁺⁺-type contact regions 15. The n⁺-type source regions 14 and the p⁺⁺-type contact regions 15, at respective upper surfaces thereof (ends thereof at the front surface of the semiconductor substrate 40), are in ohmic contact with ohmic electrodes 43.

Between the n⁻-type drift region 12 and the p-type base region 13, the n-type current spreading region 20 and the p⁺-type regions (high-concentration regions of the second conductivity type) 21 are each selectively provided at positions closer to the n⁺-type drain region 11 (back surface of the semiconductor substrate 40) than are bottoms of the trenches 16, and the p⁺-type connecting regions (connecting regions of the second conductivity type) 23 are selectively provided closer to the p-type base region 13 than are the bottoms of the trenches 16. The n⁻-type current spreading region 20, the p⁺-type regions 21, and the p⁺-type connecting regions 23 are diffused regions formed by ion implantation in the n⁻-type silicon carbide layer 42. Preferably, the n⁻-type current spreading region 20 may reach a position closer to the n⁺-type drain region 11 than are the p⁺-type regions 21.

The n⁻-type current spreading region 20 is a so-called current spreading layer (CSL) that reduces carrier spreading resistance. The n⁻-type current spreading region 20 is between and in contact with the p⁺-type regions 21 and the p⁺-type connecting regions 23 and extends in a direction parallel to the front surface of the semiconductor substrate 40, reaching the trenches 16 and being in contact with the gate insulating films 17. The n⁻-type current spreading region 20 has an upper surface in contact with the p-type base region 13 and a bottom surface in contact with the n⁻-type drift region 12.

The n⁻-type current spreading region 20 may be omitted. In an instance in which the n⁻-type current spreading region 20 is omitted, instead of the n⁻-type current spreading region 20, the n⁻-type drift region 12 reaches the p-type base region 13 and is in contact with the p-type base region 13, the p⁺-type regions 21, and the p⁺-type connecting regions 23. Further, the n⁻-type drift region 12 is in contact with the gate insulating films 17, at portions at sidewalls of the trenches 16.

The p⁺-type regions 21 and the p⁺-type connecting regions 23 are fixed to a potential of a later-described source electrode 44, deplete (or cause the n-type current spreading region 20 to deplete, or both) when the MOSFET (the silicon carbide semiconductor device 10) is off, and have a function of relaxing electric field applied to the gate insulating films 17. The p⁺-type regions 21 are provided apart from the p-type base region 13 and face the bottoms of the trenches 16 in the depth direction. The p⁺-type regions 21 are partially connected to the p⁺-type connecting regions 23 and are thereby, electrically connected to the source electrode 44. FIG. 2A depicts a cross-section of a portion where the p⁺-type connecting regions 23 are provided and the p⁺-type regions 21 and the p⁺-type connecting regions 23 are connected; FIGS. 2B and 2C depict cross-sections of portions free of the p⁺-type connecting regions 23.

The p⁺-type regions 21 may be in contact with the gate insulating films 17 at the bottoms of the trenches 16 or may be apart from the bottoms of the trenches 16. A width of each of the p⁺-type regions 21 is a same as a width of each of the trenches 16 or wider than the width of each of the trenches 16. For example, preferably, the width of each of the p⁺-type regions 21 may be two times wider than the width of each of the trenches 16 or more. The width of each of the p⁺-type regions 21 is wider than the width of each of the trenches 1, whereby the p⁺-type regions 21 also face corner portions (borders between the bottom and the sidewalls) of the bottoms of the trenches 16 in the depth direction. As a result, the effect of relaxing electric field near the bottoms of the trenches 16 by the p⁺-type regions 21 may be further increased. As depicted in FIG. 3C, in a plan view, the p⁺-type regions 21 are disposed in a striped pattern extending in a longitudinal direction of the trenches 16.

As depicted in FIG. 2A, the p⁺-type connecting regions 23 are regions connecting the p-type base region 13 and the p⁺-type regions 21, are shallower (closer to the p-type base region 13) than are the p⁺-type regions 21, and are formed at positions deeper (closer to the n⁺-type starting substrate) than are the p-type base region 13. As depicted in FIG. 3B, in a plan view, the p⁺-type connecting regions 23 are disposed in stripe-like shapes between the trenches 16, extending in a direction (lateral direction of the trenches 16) orthogonal to the longitudinal direction of the trenches 16; the p⁺-type connecting regions 23 are in contact with the trenches 16. The p⁺-type connecting regions 23 are provided in stripe-like shapes between the trenches 16, whereby the area that the p⁺-type connecting regions 23 and the p⁺-type regions 21 below the trenches 16 are in contact with each other increases, enabling the breakdown voltage to be improved. Further, as depicted in FIG. 3A, in a plan view, the p⁺⁺-type contact regions 15 are disposed periodically in dot-like shapes between the trenches 16, in the longitudinal direction of the trenches 16 and are apart from the trenches 16. The p⁺⁺-type contact regions 15 have dot-like shapes, thereby enabling properties of the silicon carbide semiconductor device 10 to be improved.

Further, preferably, a dopant concentration of the p⁺-type connecting regions 23 may be higher than a dopant concentration of the p-type base region 13 and lower than a dopant concentration of the p⁺-type regions 21. A dopant concentration of the p⁺⁺-type contact regions 15 is higher than the respective dopant concentrations of the p-type base region 13, the p⁺-type connecting regions 23, and the p⁺-type regions 21. Further, preferably, the respective dopant concentrations of the p-type base region 13, the p⁺-type connecting regions 23, and the p⁺-type regions 21 may be 1×10¹⁷/cm³ or higher.

Further, as depicted in FIGS. 3A and 3B, in a plan view, the p⁺-type connecting regions 23 are disposed in regions not overlapping the p⁺⁺-type contact regions 15. Thus, a region having the p⁺-type connecting regions 23 but free of the p⁺⁺-type contact regions 15 like that in FIG. 2A, a region free of both the p⁺-type connecting regions 23 and the p⁺⁺-type contact regions 15 like that in FIG. 2B, and a region having the p⁺⁺-type contact regions 15 but free of the p⁺-type connecting regions 23 like that in FIG. 2C are periodically disposed in the longitudinal direction of the trenches 16.

Further, in a plan view, preferably, a width of each of the p⁺-type connecting regions 23 in a direction orthogonal to the longitudinal direction of the trenches 16 may be wider than a width of each of the p⁺⁺-type contact regions 15 in a direction orthogonal to the longitudinal direction of the trenches 16. By the described configuration, the area that the p⁺-type connecting regions 23 and the p⁺-type regions 21 below the trenches 16 are in contact with each other increases and the breakdown voltage may be improved.

As described, the p⁺-type connecting regions 23 are provided shallower than are the p⁺-type regions 21 below the trenches 16 and deeper than is the p-type base region 13, whereby the area that the p⁺-type regions 21 and the p⁺⁺-type contact regions 15 are connected to each other may be increased. As a result, fluctuation of the feedback capacitance may be suppressed and SW loss may be reduced. Furthermore, the p⁺-type connecting regions 23 reduce the area that the p-type base region 13 is exposed toward a drain electrode 45, thereby making it difficult for high voltage to be applied to the p-type base region 13 and possible for the breakdown voltage to be increased.

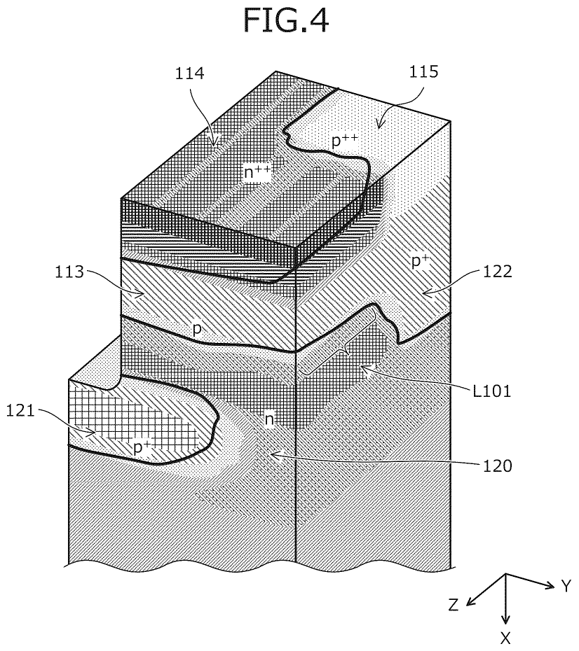

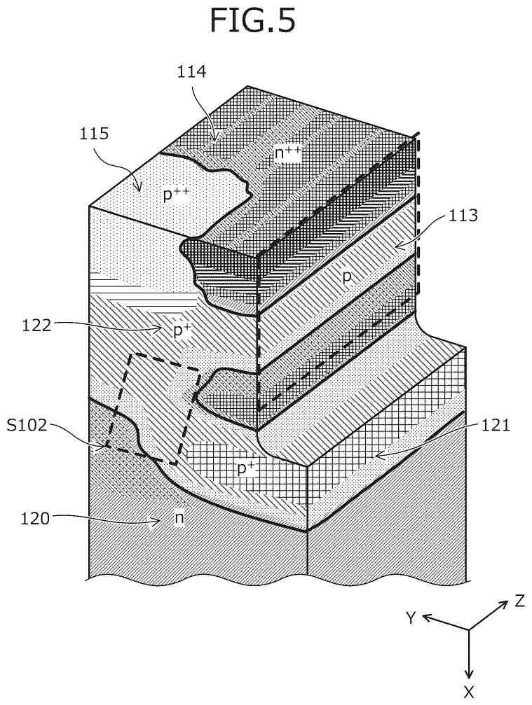

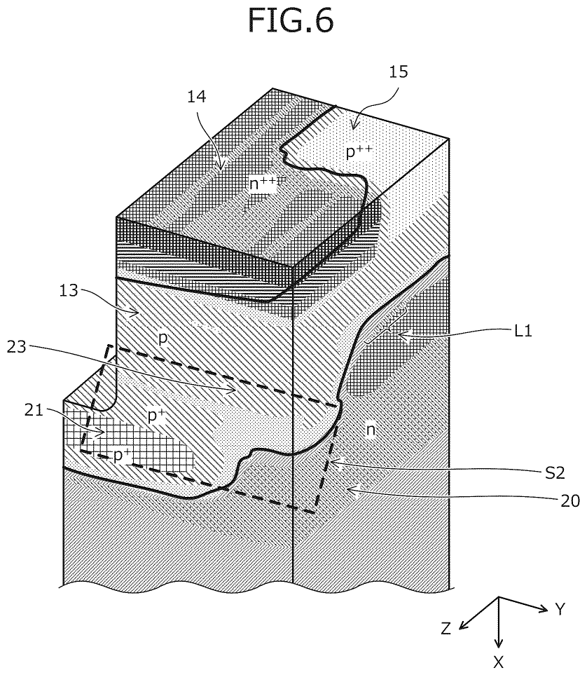

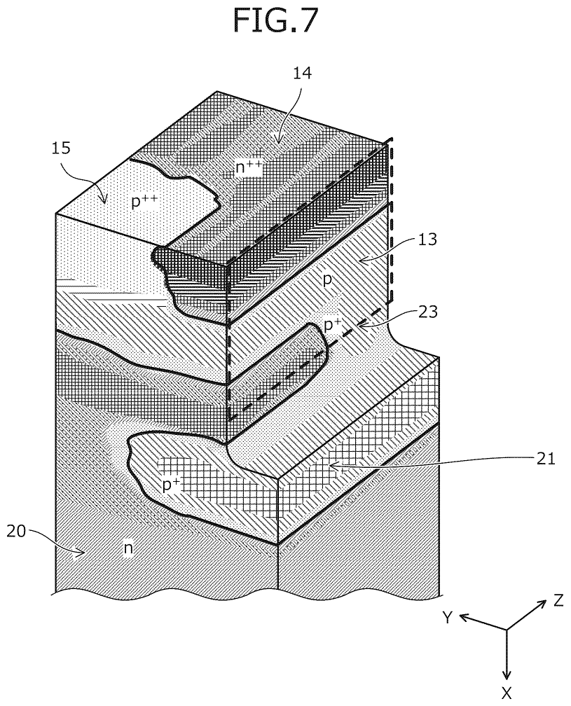

Here, FIGS. 4 and 5 are perspective views depicting a portion of the silicon carbide semiconductor device of the comparison example. FIG. 4 is a perspective view of a region S101 surrounded by a dotted line in FIG. 27 and FIG. 5 is a perspective view focused on a trench sidewall in FIG. 4, when viewed from an opposite direction. FIGS. 6 and 7 are perspective views depicting a portion of the silicon carbide semiconductor device according to the first embodiment. FIG. 6 is a perspective view of a region S1 surrounded by a dotted line in FIG. 1 and FIG. 7 is a perspective view focused on a trench sidewall in FIG. 6, when viewed from an opposite direction.

As depicted in FIG. 4, in the comparison example, a width L101 of the JFET structure below the p-type base region 113 constituting a channel region is wide. On the other hand, as depicted in FIG. 6, in the first embodiment, the width L1 of the JFET region below the p-type base region 13, which constitutes a channel region, is narrow.

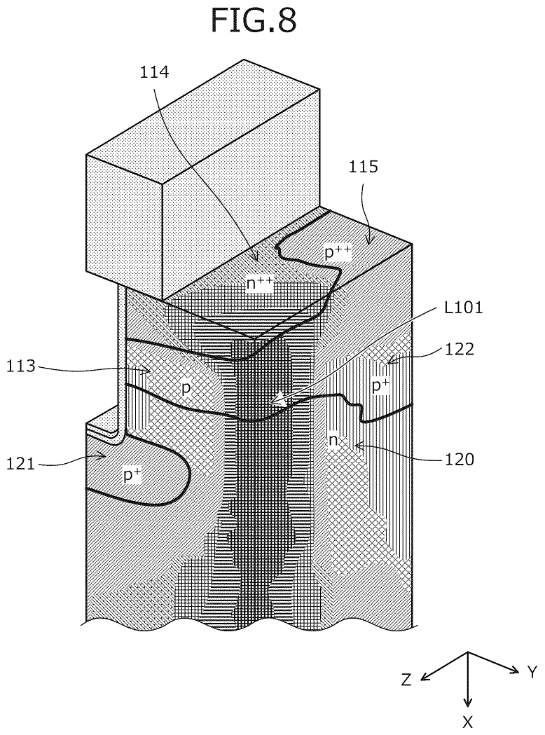

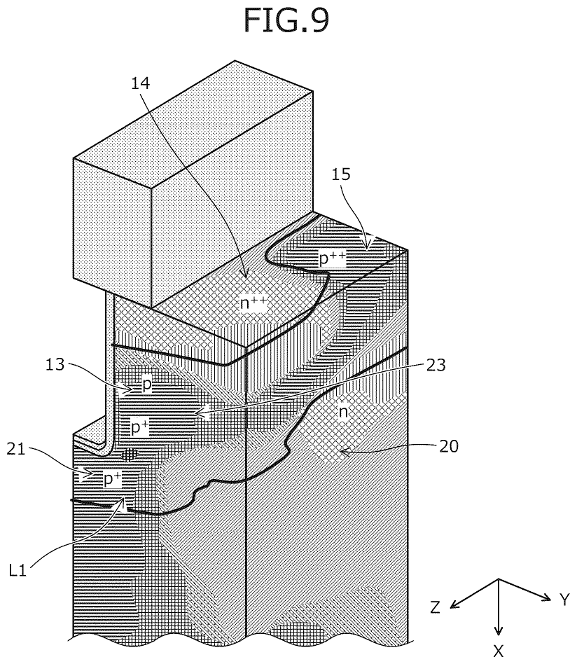

FIG. 8 is a perspective view depicting current density of the silicon carbide semiconductor device of the comparison example. FIG. 9 is a perspective view depicting current density of the silicon carbide semiconductor device according to the first embodiment. FIG. 8 depicts simulation results for drain voltage of about 1000 V and FIG. 9 depicts simulation results for drain voltage of about 1500 V and in both, darker hashing indicates higher current density. As depicted in FIG. 8, when the width L101 of the JFET region below the p-type base region 113 constituting a channel region is wide, punch-through easily occurs at the thin p-type base region 113 directly above, whereby drops in the breakdown voltage occur. On the other hand, in the first embodiment in which the p⁺-type connecting regions 23, which are shallower than the p⁺-type regions 21 directly below the trenches 16 and deeper than the p-type base region 13, are inserted between the p⁺⁺-type contact regions 15, the width L1 of the JFET region below the p-type base region 13 constituting a channel region is narrow and the breakdown voltage increases until avalanche breakdown occurs at the pn junctions. As described, in the first embodiment, the width of the JFET region below the channel region may be reduced and the breakdown voltage may be increased more than in the comparison example.

Further, as depicted in FIG. 5, in the comparison example, the region S102 where the p⁺-type regions 122 are connected to the p⁺⁺-type contact regions 115 is narrow. On the other hand, as depicted in FIG. 6, in the first embodiment, a region S2 where the p⁺-type connecting regions 23 and the p⁺⁺-type contact regions 15 are connected is wide. As described, in the first embodiment, the region S2 connected to the p⁺-type regions 21 below the trenches 16 is wider and fluctuation of the feedback capacitance decreases when high voltage is applied to the drain side, resulting in faster SW speeds.

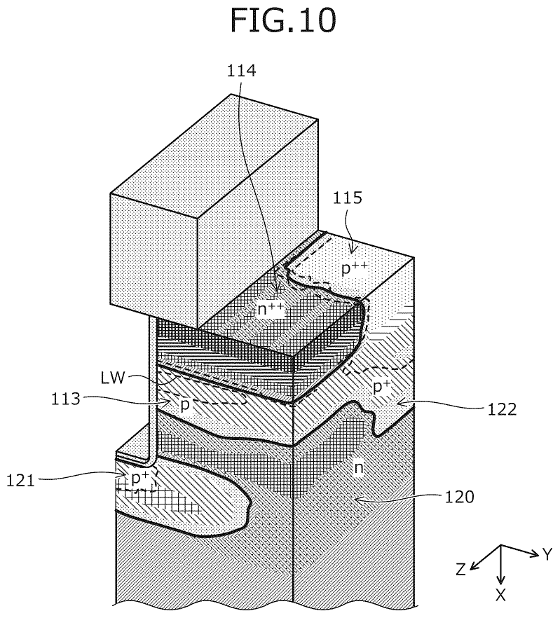

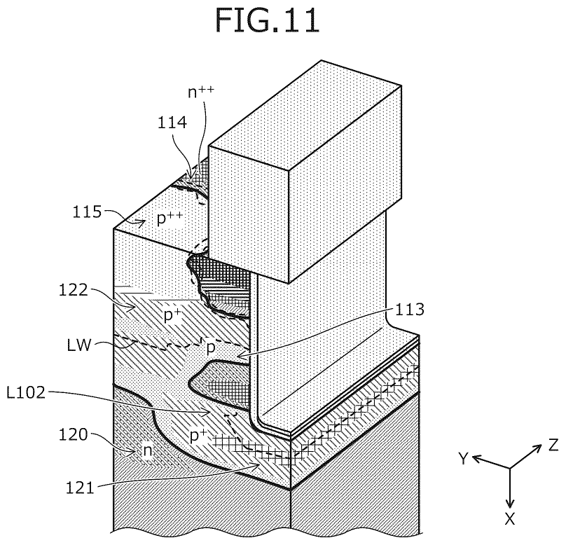

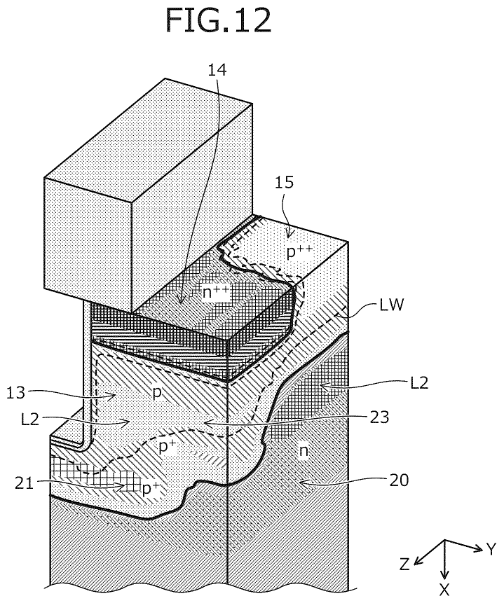

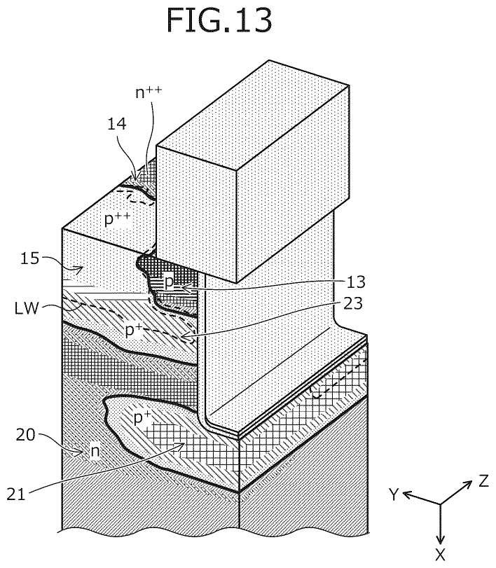

FIGS. 10 and 11 are perspective views depicting a depletion region of the silicon carbide semiconductor device of the comparison example. FIGS. 12 and 13 are perspective views depicting a depletion region of the silicon carbide semiconductor device according to the first embodiment. FIGS. 10 to 13 depict simulation results for drain voltage of about 1000 V and a portion surrounded by a dotted line LW is a depletion region. As depicted in FIGS. 10 and 11, in the comparison example, when high voltage is applied to the drain electrode, a depletion region spreads in p-type regions, between the p⁺⁺-type contact regions 122 and the p⁺-type regions 121 below the trenches 116, neutral regions are split (L102 in FIG. 11) and the feedback capacitance suddenly fluctuates. On the other hand, as depicted in FIGS. 12 and 13, in the first embodiment, even when high voltage is applied to the drain electrode, neutral regions are connected from the p⁺⁺-type contact regions 15 to the p⁺-type regions 21 below the trenches 16 (L2 in FIG. 12) and thus, without splitting of the neutral regions, fluctuation of the feedback capacitance is small.

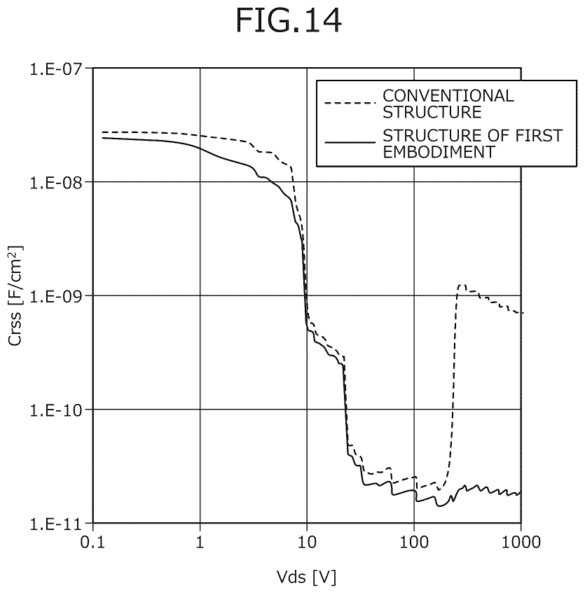

FIG. 14 is a graph depicting feedback capacitance with respect to drain voltage in the silicon carbide semiconductor device according to the first embodiment and the silicon carbide semiconductor device of the comparison example. In FIG. 14, a horizontal axis indicates drain voltage Vdsin units of V. A vertical axis indicate feedback capacitance Crss in units of F/cm². FIG. 14 depicts results of applying high voltage to the drain electrode and calculating feedback capacitance by simulation. As depicted in FIG. 14, it was found that in the silicon carbide semiconductor device of the comparison example, when the drain voltage exceeds 200 V, the feedback capacitance suddenly fluctuates greatly, however, in the silicon carbide semiconductor device according to the first embodiment, even when the drain voltage exceeds 200 V and reaches 1000 V, the feedback capacitance is nearly constant and fluctuation is suppressed.

Here, description of the structure of the silicon carbide semiconductor device 10 continues. The trenches 16 penetrate through the n⁺-type source regions 14 and the p-type base region 13 in the depth direction and reach the n-type current spreading region 20 (in an instance in which the n⁻-type current spreading region 20 is omitted, the n⁻-type drift region 12). The trenches 16 may terminate in the p⁺-type regions 21. The trenches 16, for example, extend in a striped pattern in a direction parallel to the front surface of the semiconductor substrate 40 and reach an outer peripheral portion (not depicted) of the active region. In the trenches 16, the gate electrodes 18 are provided via the gate insulating films 17.

An interlayer insulating film 19 is provided at the front surface of the semiconductor substrate 40 and particularly covers the gate electrodes 18. The ohmic electrodes (first electrodes) 43 are provided at portions the front surface of the semiconductor substrate 40 exposed in contact holes of the interlayer insulating film 19. In the contact holes of the interlayer insulating film 19, the ohmic electrodes 43 are in ohmic contact with the n⁺-type source regions 14 and the p⁺⁺-type contact regions 15 at the front surface of the semiconductor substrate 40. The ohmic electrodes 43, for example, are nickel silicide (NixSiy, where x, y are arbitrary integers) films.

The source electrode (first electrodes) 44 is provided covering the interlayer insulating film 19 so as to be embedded in the contact holes of the interlayer insulating film 19. The source electrode 44 is provided in substantially an entire area of a center portion of the active region. Further, the source electrode 44 is electrically connected to the n⁺-type source regions 14, the p⁺⁺-type contact regions 15, the p-type base region 13, the p⁺-type regions 21, and the p⁺-type connecting regions 23 via the ohmic electrodes 43.

On the ohmic electrodes 43 and the interlayer insulating film 19, a barrier metal 38 that prevents diffusion of metal atoms to the gate electrodes 18 may be provided. The barrier metal 38, for example, contains titanium (Ti) or titanium nitride (TiN). The barrier metal 38 may have a two-layer structure of Ti and TiN, the Ti being closer to the semiconductor substrate 40. In this instance, the source electrode 44 is provided on the barrier metal 38.

The drain electrode (second electrode) 45 is provided in an entire area of the back surface (back surface of the n⁺-type starting substrate 41) of the semiconductor substrate 40, is in ohmic contact with the n⁺-type drain region 11 (the n⁺-type starting substrate 41), and is electrically connected to the n⁺-type drain region 11.

Next, a method of manufacturing the silicon carbide semiconductor device according to the first embodiment is described. The silicon carbide semiconductor device according to the first embodiment is manufactured similarly to a method of manufacturing the silicon carbide semiconductor device of the comparison example. For example, manufacturing is as follows. First, at the front surface of the n⁺-type starting substrate (n⁺-type starting wafer) 41, a first n⁻-type silicon carbide layer constituting the n⁻-type drift region 12 is grown by epitaxy. Next, by ion-implantation of an n⁻-type dopant, a lower portion of the n⁻-type current spreading region 20 is formed in the first n⁻-type silicon carbide layer. Next, by photolithography and ion-implantation of a p-type dopant, the p⁺-type regions 21 are selectively formed in surface regions of the first n⁻-type silicon carbide layer.

Next, on the lower portion of the n⁻-type current spreading region 20, a second n⁻-type silicon carbide layer is grown by epitaxy. Next, by ion-implantation of an n⁻-type dopant, an upper portion of the n⁻-type current spreading region 20 is formed in the second n⁻-type silicon carbide layer. Next, a third n⁻-type silicon carbide layer is grown by epitaxy on the second n⁻-type silicon carbide layer. By the processes up to here, the semiconductor substrate (semiconductor wafer) 40 of a predetermined thickness and in which the n⁻-type silicon carbide layer 42 is stacked on the n⁺-type starting substrate 41 is completed. In the method of manufacturing, in surface regions of the first n-type silicon carbide layer, multiple sessions of epitaxy for growing the second n⁻-type silicon carbide layer and the third n⁻-type silicon carbide layer and the formation of regions by ion implantation are performed, however, the regions may be formed by photolithography and ion implantation in surface regions of the first n⁻-type silicon carbide layer.

Next, by photolithography and ion-implantation of a p-type dopant, the p-type base region 13 is formed in the third n⁻-type silicon carbide layer. Next, by photolithography and ion-implantation of an n⁻-type dopant, the n⁺-type source regions 14 are selectively formed in surface regions of the third n⁻-type silicon carbide layer.

Next, by photolithography and ion-implantation of a p-type dopant, the p⁺-type connecting regions 23 are formed in the second n⁻-type silicon carbide layer so that the lower surfaces of the p⁺-type connecting regions 23 are in contact with the p⁺-type regions 21 and the upper surfaces of the p⁺-type connecting regions 23 are in contact with the p-type base region 13. Next, by photolithography and ion-implantation of a p-type dopant, the p⁺⁺-type contact regions 15 are selectively formed in surface regions of the third n⁻-type silicon carbide layer.

A portion of the n⁻-type silicon carbide layer 42 free of ion implantation and left at the dopant concentration at the time of epitaxial growth constitutes the n⁻-type drift region 12. Next, a heat treatment for activating dopants ion-implanted in the n⁻-type silicon carbide layer 42 is performed. The heat treatment for activating dopants may be performed each time dopants are ion-implanted in the first to third n⁻-type silicon carbide layers or may be performed once for the ion implantations collectively. Next, by a general method, the trenches 16, the gate insulating films 17, and the gate electrodes 18 are formed.

Next, the interlayer insulating film 19 is formed at the front surface of the semiconductor substrate 40. Next, by a general method, the source electrode 44, a gate pad (not depicted), a passivation film (surface protective film: not depicted), and the drain electrode 45 are formed. A portion of the source electrode 44 exposed in an opening of the passivation film constitutes a source pad. Thereafter, the semiconductor wafer is diced (cut) into individual chips, thereby completing the silicon carbide semiconductor device 10 in FIGS. 1 to 3C.

As described, according to the silicon carbide semiconductor device of the first embodiment, the p⁺-type connecting regions are provided shallower than are the p⁺-type regions below the trenches and deeper than is the p-type base region. As a result, the area that the p⁺-type regions and the p⁺⁺-type contact regions are connected to each other may be increased, fluctuation of the feedback capacitance may be suppressed, and SW loss may be reduced. Furthermore, the p⁺-type connecting regions reduce the area that the p-type base region is exposed toward the drain electrode, thereby making it difficult for high voltage to be applied to the p-type base region 13 and possible for the breakdown voltage to be increased.

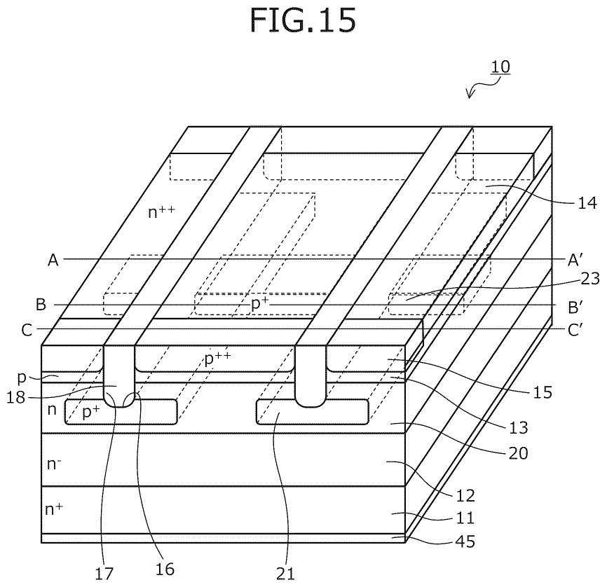

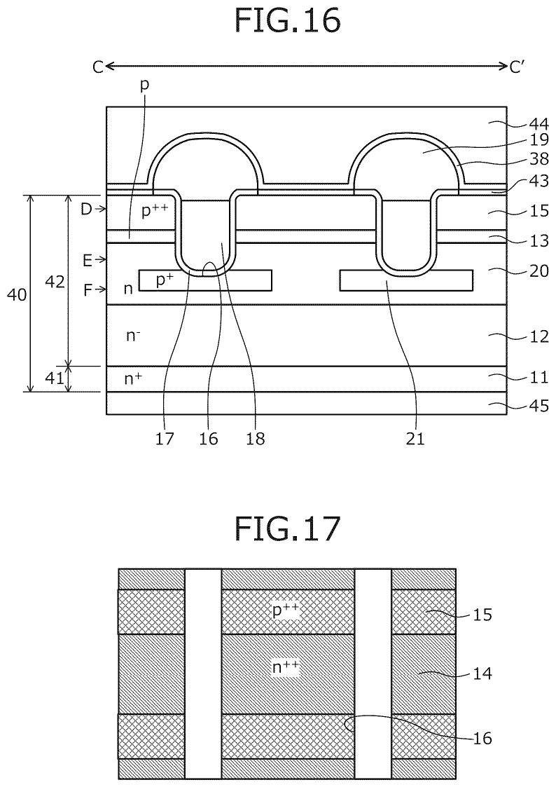

Next, the structure of the silicon carbide semiconductor device according to a second embodiment is described. FIG. 15 is a perspective view depicting the structure of the silicon carbide semiconductor device according to the second embodiment. FIG. 16 is a cross-sectional view depicting the structure of the silicon carbide semiconductor device according to the second embodiment, along cutting line C-C′ in FIG. 15. FIG. 17 is a plan view depicting the structure of the silicon carbide semiconductor device according to the second embodiment, at a depth D in FIG. 16. A cross-sectional view along cutting line A-A′ in FIG. 15 and a cross-sectional view along cutting line B-B′ in FIG. 15 are, respectively, a same as the cross-sectional view along cutting line A-A′ in FIG. 1 and the cross-sectional view along cutting line B-B′ in FIG. 1, a plan view at the depth E in FIG. 16 and a plan view at the depth F in FIG. 16 are, respectively, a same as the plan view at the depth E indicated in FIGS. 2A to 2C, and a plan view at the depth F is a same as the plan view at the depth F indicated in FIGS. 2A to 2C and thus, are not depicted.

The silicon carbide semiconductor device 10 according to the second embodiment differs from the silicon carbide semiconductor device 10 according to the first embodiment in that the p⁺⁺-type contact regions 15 are provided in stripe-like shapes between the trenches 16. As depicted in FIGS. 15 to 17, in a plan view, the p⁺⁺-type contact regions 15 are disposed periodically in the longitudinal direction of the trenches 16, in stripe-like shapes between the trenches 16; the p⁺⁺-type contact regions 15 are in contact with the trenches 16.

As described, the p⁺⁺-type contact regions 15 are provided in stripe-like shapes between the trenches 16, whereby misalignment of the p⁺⁺-type contact regions 15 does not occur and manufacturing costs may be reduced compared to that of the first embodiment in which the p⁺⁺-type contact regions 15 are provided in dot-like shapes.

As described, according to the silicon carbide semiconductor device of the second embodiment, similar to the first embodiment, the p⁺-type connecting regions are provided. As a result, similar to the first embodiment, fluctuation of the feedback capacitance may be suppressed, SW loss may be reduced, and the breakdown voltage may be increased. Further, in the second embodiment, the p⁺⁺-type contact regions are provided in stripe-like shapes between the trenches, whereby misalignment of the p⁺⁺-type contact regions does not occur and manufacturing costs may be reduced as compared to that of the first embodiment.

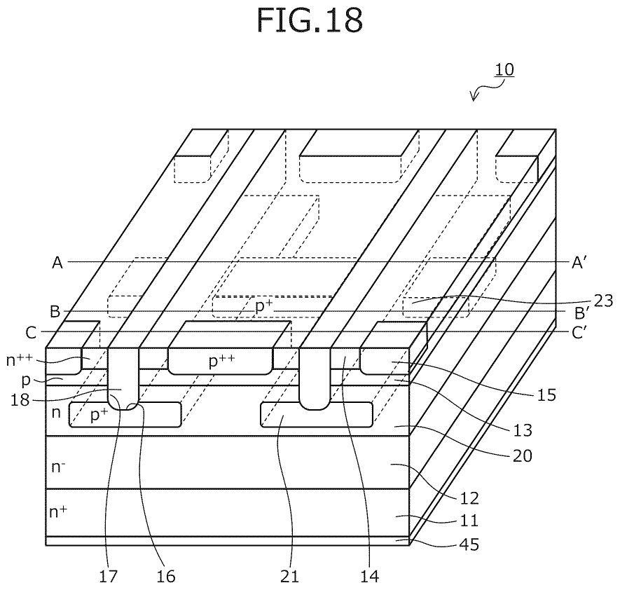

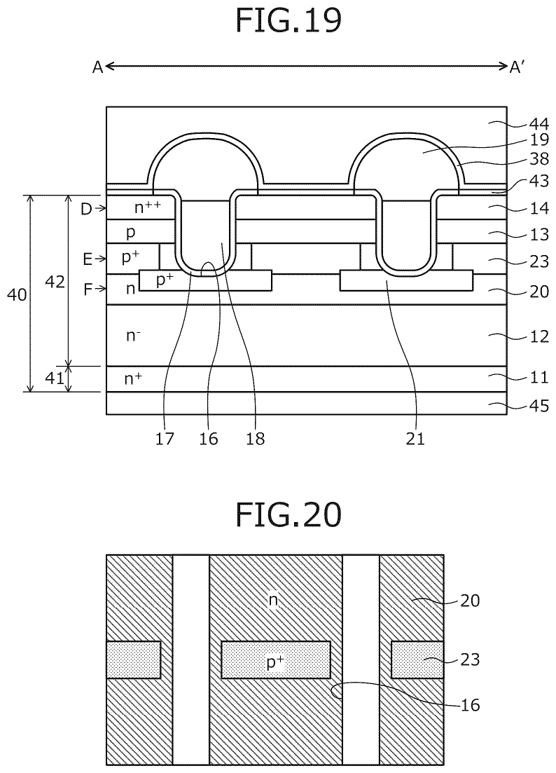

Next, the structure of the silicon carbide semiconductor device according to a third embodiment is described. FIG. 18 is a perspective view depicting the structure of the silicon carbide semiconductor device according to the third embodiment. FIG. 19 is a cross-sectional view of the structure of the silicon carbide semiconductor device according to the third embodiment, along cutting line A-A′ in FIG. 18. FIG. 20 is a plan view of the structure of the silicon carbide semiconductor device according to the third embodiment, at the depth E in FIG. 18. A cross-sectional view along cutting line B-B′ in FIG. 18 and a cross-sectional view along cutting line C-C′ in FIG. 18 are, respectively, a same as the cross-sectional view along cutting line B-B′ in FIG. 1 and the cross-sectional view along cutting line C-C′ in FIG. 1, and a plan view at the depth D in FIG. 19 and a plan view at the depth F in FIG. 19 are, respectively, a same as the plan view at the depth D indicated in FIGS. 2A to 2C, and a plan view at the depth F is a same as the plan view at the depth F indicated in FIGS. 2A to 2C and thus, are not depicted.

The silicon carbide semiconductor device 10 according to the third embodiment differs from the silicon carbide semiconductor device 10 according to the first embodiment in that the p⁺-type connecting regions 23 are provided in dot-like shapes. As depicted in FIGS. 18 to 20, in a plan view, the p⁺-type connecting regions 23 are disposed in dot-like shapes in a direction orthogonal to the longitudinal direction of the trenches 16 and are apart from the trenches 16. As described, the p⁺-type connecting regions 23 are provided in dot-like shapes, whereby the channel region is wider and the resistance may lower as compared to the first embodiment in which the p⁺-type connecting regions 23 are provided in stripe-like shapes between the trenches 16.

As described, according to the silicon carbide semiconductor device of the third embodiment, similar to the first embodiment, the p⁺-type connecting regions are provided. As a result, similar to the first embodiment, fluctuation of the feedback capacitance may be suppressed, SW loss may be reduced, and the breakdown voltage may be increased. Further, in the third embodiment, the p⁺-type connecting regions are provided in dot-like shapes, whereby the channel region is wider and the resistance may be lower than in the first embodiment.

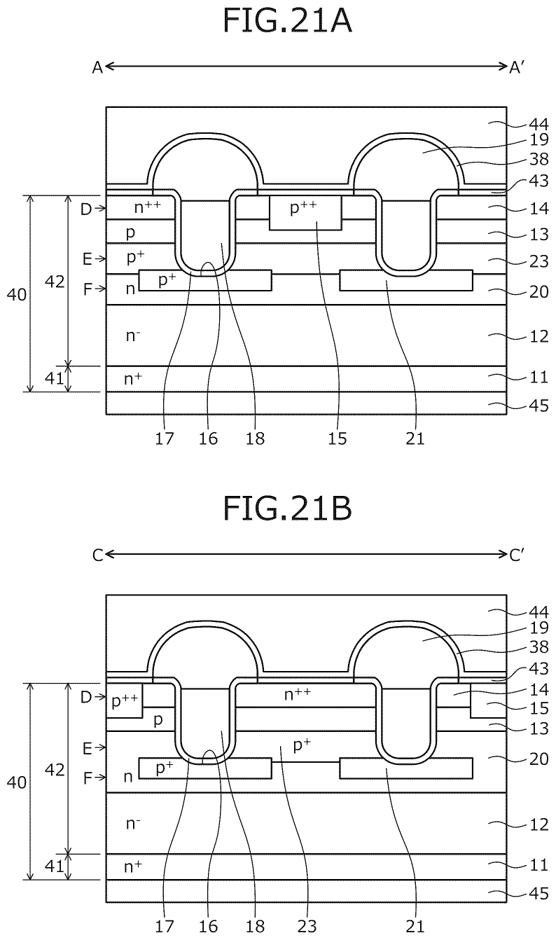

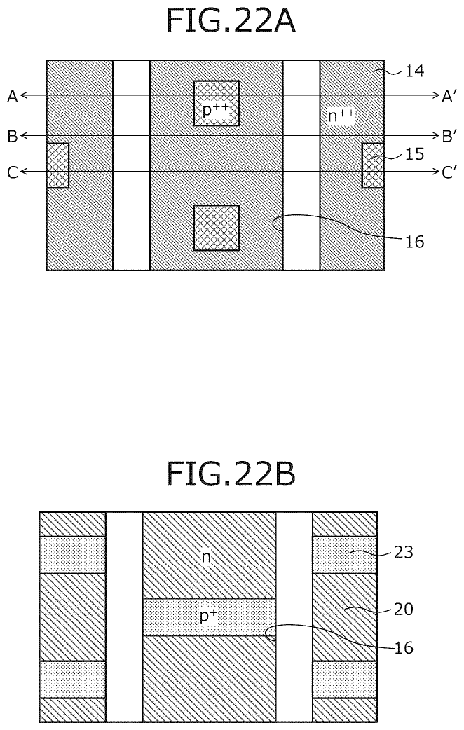

Next, the structure of the silicon carbide semiconductor device according to a fourth embodiment is described. In the fourth embodiment, perspective views are not depicted. FIG. 21A is a cross-sectional view depicting the structure of the silicon carbide semiconductor device according to the fourth embodiment, along cutting line A-A′ in FIG. 22A. FIG. 21B is a cross-sectional view depicting the structure of the silicon carbide semiconductor device according to the fourth embodiment, along cutting line C-C′ in FIG. 22A. FIG. 22A is a plan view of the structure of the silicon carbide semiconductor device according to the fourth embodiment depicted in FIG. 21A, at the depth D in FIG. 21B. FIG. 22B is a plan view of the structure of the silicon carbide semiconductor device according to the fourth embodiment depicted in FIG. 21A, at the depth E in FIG. 21B. A cross-sectional view along cutting line B-B′ in FIG. 22A is a same as the cross-sectional view along cutting line B-B′ in FIG. 1 and a plan view at the depth F in FIGS. 21A and 21B is a same as the plan view at the depth F in FIGS. 2A to 2C and thus, are not depicted.

The silicon carbide semiconductor device 10 according to the fourth embodiment differs from the silicon carbide semiconductor device 10 according to the first embodiment in that positions where the p⁺-type connecting regions 23 and the p⁺⁺-type contact regions 15 are disposed are different. As depicted in FIGS. 22A and 22B, between the adjacent trenches 16, while the p⁺-type connecting regions 23 are disposed periodically in the longitudinal direction of the trenches 16, the p⁺-type connecting regions 23 are not disposed where the p⁺⁺-type contact regions 15 are disposed. Similarly, between the adjacent trenches 16, while the p⁺⁺-type contact regions 15 are periodically disposed in the longitudinal direction of the trenches 16, the p⁺⁺-type contact regions 15 are not disposed where the p⁺-type connecting regions 23 are disposed.

As described, according to the silicon carbide semiconductor device of the fourth embodiment, even when the p⁺⁺-type contact regions are disposed without disposing the p⁺-type connecting regions between adjacent trenches, effects similar to those of the first embodiment are obtained.

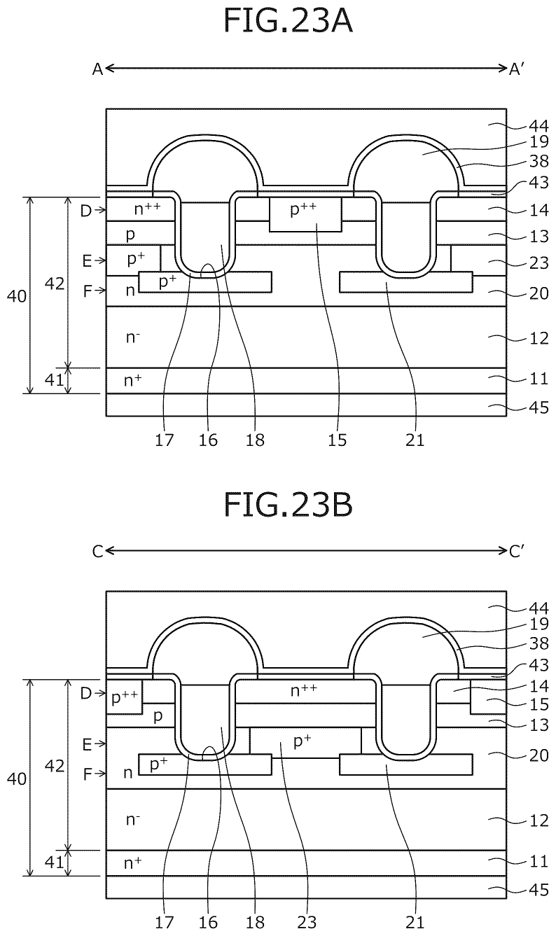

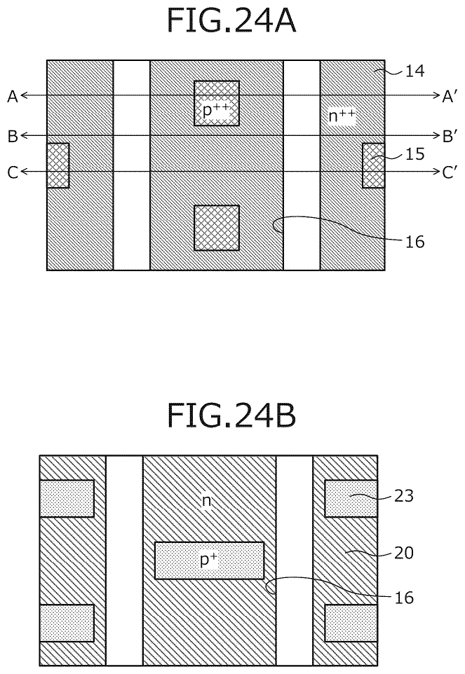

Next, the structure of the silicon carbide semiconductor device according to a fifth embodiment is described. In the fifth embodiment, perspective views are not depicted. FIG. 23A is a cross-sectional view of the structure of the silicon carbide semiconductor device according to the fifth embodiment, along cutting line A-A′ in FIG. 24A. FIG. 23B is a cross-sectional view of the structure of the silicon carbide semiconductor device according to the fifth embodiment, along cutting line C-C′ in FIG. 24A. FIG. 24A is a plan view of the structure of the silicon carbide semiconductor device according to the fifth embodiment depicted in FIG. 23A, at the depth D in FIG. 23B. FIG. 24B is a plan view of the structure of the silicon carbide semiconductor device according to the fifth embodiment depicted in FIG. 23A, at the depth E in FIG. 23B. A cross-sectional view along cutting line B-B′ in FIG. 24A is a same as the cross-sectional view along cutting line B-B′ in FIG. 1, and a plan view at the depth F in FIGS. 23A and 23B is a same as the plan view at the depth F in FIGS. 2A to 2C and thus, are not depicted.

The silicon carbide semiconductor device according to the fifth embodiment differs from the silicon carbide semiconductor device according to the fourth embodiment in that the p⁺-type connecting regions 23 are provided in dot-like shapes. As depicted in FIG. 24B, in a plan view, the p⁺-type connecting regions 23 are disposed in dot-like shapes in a direction orthogonal to the longitudinal direction of the trenches 16 and are apart from the trenches 16. As described, the p⁺-type connecting regions 23 are provided in dot-like shapes, whereby the channel region is wider and the resistance may be lower as compared to the fourth embodiment in which the p⁺-type connecting regions 23 are provided in stripe-like shapes between the trenches 16.

As described, according to the silicon carbide semiconductor device of the fifth embodiment, between adjacent trenches, even when the p⁺⁺-type contact regions are disposed without disposing the p⁺-type connecting regions, effects similar to those of the first embodiment are obtained. Further, in the fifth embodiment, the p⁺-type connecting regions are provided in dot-like shapes, whereby the channel region is wider and the resistance may be lower than in the fourth embodiment.

Further, in a configuration in which the p⁺-type connecting regions 23 and the p⁺⁺-type contact regions 15 are each arranged in a single row in a direction orthogonal to the longitudinal direction of the trenches 16, in addition to the first to third embodiments, the p⁺-type connecting regions 23 may have dot-like shapes and the p⁺⁺-type contact regions 15 may have stripe-like shapes between the trenches 16.

Further, in a configuration in which the p⁺-type connecting regions 23 and the p⁺⁺-type contact regions 15 are arranged in a single row, alternating each other in a direction orthogonal to the longitudinal direction of the trenches 16, in addition to configurations of the fourth and fifth embodiments, between the trenches 16, the p⁺-type connecting regions 23 may have stripe-like shapes and the p⁺⁺-type contact regions 15 may have stripe-like shapes, or the p⁺-type connecting regions 23 may have dot-like shapes and the p⁺⁺-type contact regions 15 may have stripe-like shapes.

In the foregoing, the present disclosure may be variously modified within a range not departing from the spirit of the disclosure and in the embodiments described above, for example, dimensions, dopant concentrations, and the like are variously set according to necessary specifications. Further, in the embodiments described above, while a MOSFET having a trench structure is described as an example, application to another semiconductor device having a trench structure such as an IGBT is possible.

According to the disclosure above, the p⁺-type connecting regions (plurality of connecting regions) are provided shallower than are the p⁺-type regions (high-concentration regions below the trenches) and deeper than is the p-type base region (second semiconductor layer). As a result, the area that the p⁺-type regions and the p⁺⁺-type contact regions are connected to each other may be increased, fluctuation of the feedback capacitance may be suppressed, and SW loss may be reduced. Furthermore, the p⁺-type connecting regions reduce the area that the p-type base region is exposed toward the drain electrode and thus, high voltage is not easily applied to the p-type base region, and the breakdown voltage may be increased.

The silicon carbide semiconductor device according to the present disclosure achieves an effect in that reduced cell pitch, increased breakdown voltage, and reduced resistance may be realized.

As described, the silicon carbide semiconductor device according to the present disclosure is useful for power semiconductor devices used in power converting equipment such as inverters, power source devices of various types of industrial machines, igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a silicon carbide semiconductor substrate of a first conductivity type, the silicon carbide semiconductor substrate having a first main surface and a second main surface opposite to each other;
a first semiconductor layer of the first conductivity type, provided at the first main surface of the silicon carbide semiconductor substrate, the first semiconductor layer having a dopant concentration lower than a dopant concentration of the silicon carbide semiconductor substrate, the first semiconductor layer having a first surface and a second surface opposite to each other, the second surface facing the silicon carbide semiconductor substrate;
a second semiconductor layer of a second conductivity type, provided at the first surface of the first semiconductor layer, the second semiconductor layer having a first surface and a second surface opposite to each other, the second surface facing the first semiconductor layer;
a plurality of first semiconductor regions of the first conductivity type, selectively provided in the second semiconductor layer at the first surface thereof;
a plurality of second semiconductor regions of the second conductivity type, selectively provided in the second semiconductor layer at the first surface thereof, the plurality of second semiconductor regions being in contact with the plurality of first semiconductor regions and the second semiconductor layer;
a plurality of trenches penetrating through the plurality of first semiconductor regions and the second semiconductor layer and reaching the first semiconductor layer;
a plurality of gate insulating films respectively provided in the plurality of trenches;
a plurality of gate electrodes respectively provided on the plurality of gate insulating films, in the plurality of trenches;
a plurality of high-concentration regions of the second conductivity type, provided in the first semiconductor layer, respectively at positions facing the plurality of trenches in a depth direction;
a plurality of connecting regions of the second conductivity type, selectively provided in the first semiconductor layer, closer to the second semiconductor layer than is the plurality of high-concentration regions and closer to the silicon carbide semiconductor substrate than is the second semiconductor layer, the plurality of connecting regions being in contact with the plurality of high-concentration regions and the second semiconductor layer;
a plurality of first electrodes provided at surfaces of the plurality of first semiconductor regions and surfaces of the plurality of second semiconductor regions; and
a second electrode provided at the second main surface of the silicon carbide semiconductor substrate, wherein
the plurality of second semiconductor regions is periodically disposed in a longitudinal direction of the plurality of trenches, and
the plurality of connecting regions is disposed periodically in the longitudinal direction of the plurality of trenches, in regions not overlapping with the plurality of second semiconductor regions in a plan view of the silicon carbide semiconductor device.

2. The silicon carbide semiconductor device according to claim 1, wherein in a direction orthogonal to the longitudinal direction of the plurality of trenches, a width of each of the plurality of connecting regions is wider than a width of each of the plurality of second semiconductor regions in the plan view.

3. The silicon carbide semiconductor device according to claim 1, wherein
each of the plurality of connecting regions is formed of a plurality of sections, each section, in the plan view, being provided between adjacent two of the plurality of trenches, and apart from the plurality of trenches.

4. The silicon carbide semiconductor device according to claim 1, wherein
each of the plurality of connecting regions is formed of a plurality of sections, each section, in the plan view, being provided between adjacent two of the plurality of trenches, orthogonal to the longitudinal direction of the plurality of trenches, and being in contact with the adjacent two of the plurality of trenches.

5. The silicon carbide semiconductor device according to claim 3, wherein
each of the plurality of second semiconductor regions, in the plan view, is provided between adjacent two of the plurality of trenches, and apart from the adjacent two of the plurality of trenches.

6. The silicon carbide semiconductor device according to claim 4, wherein
each of the plurality of second semiconductor regions, in the plan view, is provided between adjacent two of the plurality of trenches, and apart from the adjacent two of the plurality of trenches.

7. The silicon carbide semiconductor device according to claim 3, wherein
each of the plurality of second semiconductor regions, in the plan view, is provided between adjacent two of the plurality of trenches, orthogonal to the longitudinal direction of the plurality of trenches, and is in contact with the adjacent two of the plurality of trenches.

8. The silicon carbide semiconductor device according to claim 4, wherein
each of the plurality of second semiconductor regions, in the plan view, is provided between adjacent two of the plurality of trenches, orthogonal to the longitudinal direction of the plurality of trenches, and is in contact with the adjacent two of the plurality of trenches.

9. The silicon carbide semiconductor device according to claim 1, wherein
a dopant concentration of the plurality of connecting regions is higher than a dopant concentration of the second semiconductor layer and lower than a dopant concentration of the plurality of high-concentration regions.

10. The silicon carbide semiconductor device according to claim 1, wherein
a dopant concentration of each of the second semiconductor layer, the plurality of connecting regions, and the plurality of high-concentration regions is 1×10¹⁷/cm³ or higher.
